(19) United States
(12) Patent Application Publication
(10) Pub. No.: US 2023/0244444 A1
(43) Pub. Date: Aug. 3, 2023

(54) DSP IMPLEMENTATION OF NONLINEAR DIFFERENTIATORS

(71) Applicant: KING FAHD UNIVERSITY OF PETROLEUM AND MINERALS, Dhahran (SA)

(72) Inventor: Salim IBRIR, Dhahran (SA)

(73) Assignee: KING FAHD UNIVERSITY OF PETROLEUM AND MINERALS, Dhahran (SA)

(21) Appl. No.: 17/590,282

(22) Filed: Feb. 1, 2022

(51) Int. Cl. G06F 7/483; G06F 7/485; H03M 1/08; H03M 1/12; H03M 1/66

(52) U.S. Cl. CPC G06F 7/4833; G06F 7/485; H03M 1/08; H03M 1/12; H03M 1/66

(57) ABSTRACT

Methods of nonlinear differentiation and nonlinear differentiators are described. A log-sign nonlinear differentiator and an adaptive gain log-sign differentiator for signal tracking in a digital signal processor receive an input signal, u(t), estimates a filtered first state, x₁(t) of the input signal, estimates second state signal, x₂(t), and receive parameters which cause the filtered first state, x₁(t), to converge asymptotically to the input signal, u(t), and the second state signal, x₂(t), to converge asymptotically to the first derivative \dot{u}(t) of the input signal, u(t), such that a first output, y₁(t), of the log-sign nonlinear differentiator, is an estimate of the input signal, u(t), and a second output, y₂(t) equals the first derivative, \dot{u}(t) of the input signal, u(t), tracked by the log-sign nonlinear differentiator. The adaptive log-sign differentiator includes a signal path which includes calculating a deadzone function at the input of the first differentiator.

### BACKGROUND

### Technical Field

The present disclosure is directed to signal tracking systems and methods. In particular, the present disclosure relates to Digital Signal Processing (DSP) implementation of nonlinear differentiators.

### Description of Related Art

The “background” description provided herein is for the purpose of generally presenting the context of the disclosure. Work of the presently named inventors, to the extent it is described in this background section, as well as aspects of the description which may not otherwise qualify as prior art at the time of filing, are neither expressly or impliedly admitted as prior art against the present invention.

Signal differentiation is a well-known problem in mathematical analysis. Signal differentiation is also a research topic of importance in signal processing and control engineering applications. In many situations, when an explicit expression of a signal is known, its first derivative can be easily computed using standard methods of differentiation. However, when the signal is not known, its higher derivatives may be estimated using numerical techniques such as a finite-difference method. For using the finite-difference method, at least two samples of the signal should be known in order to evaluate the first derivative. However, precise approximation of the first derivatives requires a large number of samples that are generally previous values of the signal collected during a fixed period. Further classical finite-difference methods are not robust enough to deal with measurements that are corrupted by unknown noise. Therefore, estimating the first or the higher derivatives of unknown signals is a challenging problem. Also estimating the first or the higher derivatives of unknown signals is classified as an ill-posed problem when some of the signal samples are missing or unavailable for measurement.

Considering some applications such as spectroscopy, differentiation of spectra is a widely used technique, particularly in infra-red, ultraviolet, visible absorption, fluorescence, and reflectance spectrophotometry, referred to as derivative spectroscopy. In target tracking, a need for a first derivative is a core problem in estimating or anticipating the position of a target. A trace analysis is based upon an estimation of a signal derivative to trace small amounts of substances that are mixed with large amounts of potentially interfering materials. The information of the time derivative of systems outputs is required to build stabilizing feedbacks, and in many situations, the higher derivatives are needed to steer the systems to desired equilibrium points.

Thus, known finite-differences methods and other methods suffer from one or more drawbacks such as not being robust enough to deal with measurements that are corrupted by unknown noise, which hinders their adoption. Furthermore, estimating first or higher derivatives of unknown signals accurately is challenging when some of the signal samples are missing or unavailable for measurement. Without the first derivatives or higher derivatives, it may be challenging to steer the systems to the desired equilibrium points. Accordingly, it is one object of the present disclosure to provide methods and systems including nonlinear differentiators for signal tracking and deriving first derivatives or higher derivatives.

### SUMMARY

In an exemplary embodiment, a method of using a log-sign nonlinear differentiator for signal tracking in a digital signal processor comprising a signal interface and a circuitry for digital signal processing is disclosed. The method includes receiving, via the signal interface, an input signal, u(t), to be tracked by the log-sign nonlinear differentiator, estimating, with the circuitry, a filtered first state, x₁(t) of the input signal, estimating, with the circuitry, a second state signal, x₂(t), wherein the second state signal, x₂(t), represents an estimate of a first derivative, \dot{u}(t), of the input signal, u(t), and receiving, via the signal interface, a set of parameters (α, β, γ, ε, λ) which cause the filtered first state, x₁(t), to converge asymptotically to the input signal, u(t), and the second state signal, x₂(t), to converge asymptotically to the first derivative \dot{u}(t) of the input signal, u(t), such that a first output, y₁(t), of the log-sign nonlinear differentiator, is an estimate of the input signal, u(t), tracked by the log-sign nonlinear differentiator, and a second output, y₂(t) equals the first derivative, \dot{u}(t) of the input signal, u(t) and indicates a direction of the input signal, u(t), tracked by the log-sign nonlinear differentiator.

In another exemplary embodiment, a log-sign nonlinear differentiator for signal tracking, is disclosed. The log-sign nonlinear differentiator includes an analog-to-digital converter configured to receive an analog input signal and convert the analog signal to a digital signal, u(t), an first adder configured to receive a filtered first state signal, x₁(t), subtract the filtered first state signal, x₁(t), from the digital signal, u(t), and generate an error signal, v(t), a first log-sign differentiator configured to receive the error signal, v(t), and estimate a first derivative, \dot{x}₁(t), of the filtered first state signal, x₁(t), a second log-sign differentiator configured to receive the error signal, v(t), and generate an estimate of a second derivative, \dot{x}₂(t), of the input signal, u(t), a first integrator connected in series with the second log-sign differentiator, wherein the first integrator is configured to integrate the second derivative, \dot{x}₂(t), and generate a second state signal, x₂(t), wherein the second state signal, x₂(t), represents an estimate of a first derivative, \dot{u}(t), of the input signal, u(t), a second adder configured to add the first derivative, \dot{x}₁(t), of the filtered first state signal, x₁(t), to the second state signal, x₂(t), thus generating a summed signal, a second integrator configured to integrate the summed signal and generate the filtered first state signal, x₁(t), a first digital to analog converter configured to convert the filtered first state signal, x₁(t) to an estimate of the input signal, u(t), and a second digital to analog converter configured to convert the second state signal to an estimate of the first derivative, \dot{u}(t), of the input signal, u(t), such that a first tracked output, y₁(t), of the log-sign nonlinear differentiator, is an estimate of the input signal, u(t), tracked by the log-sign nonlinear differentiator, and a second output, y₂(t) equals the first derivative, \dot{u}(t) of the input signal, u(t), indicating a tracked direction of the input signal, u(t).

In another exemplary embodiment, an adaptive gain log-sign differentiator for signal tracking is disclosed. The adaptive gain log-sign differentiator includes an analog-to-digital converter configured to receive an analog input signal and convert the analog signal to a digital signal, u(t), an first adder configured to receive a filtered first state signal, x₁(t), subtract the filtered first state signal, x₁(t), from the digital signal, u(t), and generate an error signal, v(t), a deadzone function calculator configured to receive the error signal, v(t) and a first gain parameter, λ, where λ>0, and multiply a deadzone function, Dε(|u(t)−x₁(t)|), by the first gain parameter, λ, to generate a weighted deadzone function, a first integrator configured to integrate the weighted deadzone function and generate a gain value, γ(t), of the deadzone function, where γ(0)>0 and γ(t) is an increasing positive function of time, t, a first log-sign differentiator configured to receive the error signal, v(t), and the gain value, γ(t), and estimate a first derivative, \dot{x}₁(t), of the filtered first state signal, x₁(t), a second log-sign differentiator configured to receive the error signal, v(t), and the gain value, γ(t), and generate an estimate of a second derivative, \dot{x}₂(t), of the input signal, u(t); a second integrator connected in series with the second log-sign differentiator, wherein the second integrator is configured to integrate the estimate of the second derivative, \dot{x}₂(t), and generate a second state signal, x₂(t), wherein the second state signal, x₂(t), represents an estimate of a first derivative, \dot{u}(t), of the input signal, u(t), a second adder configured to add the first derivative, \dot{x}₁(t), of the filtered first state signal, x₁(t), to the second state signal, x₂(t), thus generating a summed signal; a third integrator configured to integrate the summed signal and generate the filtered first state signal, x₁(t); a first digital to analog converter configured to convert the filtered first state signal, x₁(t), to an estimate of the input signal, u(t), and a second digital to analog converter configured to convert the second state signal to an estimate of the first derivative, \dot{u}(t) of the input signal, u(t), such that a first tracked output, y₁(t), of the adaptive log-sign differentiator, is an estimate of the input signal, u(t), and a second tracked output, y₂(t), of the adaptive log-sign differentiator, equals the first derivative, \dot{u}(t) of the input signal, u(t), indicating a tracked direction of the input signal, u(t).

The foregoing general description of the illustrative embodiments and the following detailed description thereof are merely exemplary aspects of the teachings of this disclosure, and are not restrictive.

### BRIEF DESCRIPTION OF THE DRAWINGS

A more complete appreciation of this disclosure and many of the attendant advantages thereof will be readily obtained as the same becomes better understood by reference to the following detailed description when considered in connection with the accompanying drawings, wherein:

FIG. 1 illustrates an architecture of a log-sign nonlinear differentiator, according to certain embodiments.

FIG. 2 illustrates an architecture of an adaptive gain log-sign nonlinear differentiator, according to certain embodiments.

FIG. 3 is an exemplary illustration of phase map with α=2 and β=2.1, according to certain embodiments.

FIG. 4 illustrates a deadzone function parameterized by a parameter ε, according to certain embodiments.

FIG. 5 illustrates a convergence of a first state x₁(t) to an input signal u(t), according to certain embodiments.

FIG. 6 illustrates an estimate of the first derivative of u(t) along with a time-derivative of the input signal u(t), according to certain embodiments.

FIG. 7 illustrates a noisy signal u(t) along with a first state x₁(t), according to certain embodiments.

FIG. 8 illustrates the first state x₁(t) and a noise-free signal along with u(t), according to certain embodiments.

FIG. 9 illustrates an adaptive gain log-sign differentiator output and an exact derivative of noise-free signal, according to certain embodiments.

FIG. 10 illustrates a stand-alone controller board in which the differentiators are implemented for experimentation, according to certain embodiments.

FIG. 11 illustrates the input signal u(t) corrupted by noise and a differentiator state x₁(t) of the log-sign nonlinear differentiator, according to certain embodiments.

FIG. 12 illustrates a noise-free signal \dot{u}(t) and a real-time differentiator state x₂(t) of the log-sign nonlinear differentiator, according to certain embodiments.

FIG. 13 illustrates the input signal u(t) corrupted by noise and the differentiator state x₁(t), according to certain embodiments.

FIG. 14 illustrates a noise-free first derivative \dot{u}(t) and the real-time differentiator state x₂(t), according to certain embodiments.

FIG. 15 is an illustration of a non-limiting example of details of computing hardware used in the computing device, according to aspects of the present disclosure.

FIG. 16 is an exemplary schematic diagram of a data processing system used within the computing device, according to aspects of the present disclosure.

FIG. 17 is an exemplary schematic diagram of a processor used with the computing device, according to aspects of the present disclosure.

FIG. 18 is an illustration of a non-limiting example of distributed components that may share processing with the controller, according to aspects of the present disclosure.

### DETAILED DESCRIPTION

In the drawings, like reference numerals designate identical or corresponding parts throughout the several views. Further, as used herein, the words “a,” “an” and the like generally carry a meaning of “one or more,” unless stated otherwise.

Furthermore, the terms “approximately,” “approximate,” “about,” and similar terms generally refer to ranges that include the identified value within a margin of 20%, 10%, or preferably 5%, and any values therebetween.

Aspects of this disclosure are directed to a system, device, and method for robust nonlinear differentiators. In an example, a differentiator is formulated as a two-dimensional nonlinear dynamical system exhibiting a “log” function and a “sign” function (referred to as a “log-sign” nonlinear differentiator). A first state of the log-sign nonlinear differentiator represents a filtered estimate of a system input, while a second state denotes an estimate of a first derivative of the system input. By appropriate selection of the system parameters, the first state and the second states of the nonlinear system converge asymptotically to an exact input and its first derivative, respectively. In another aspect, an adaptive gain log-sign differentiator is disclosed. The adaptive gain log-sign differentiator reproduces the system input and its first derivative irrespective of the maximum value that can reach a second derivative of the system input. The adaptive gain log-sign differentiator is robust against additive noise corrupting an input measurement.

### The Log-Sign Nonlinear Differentiator

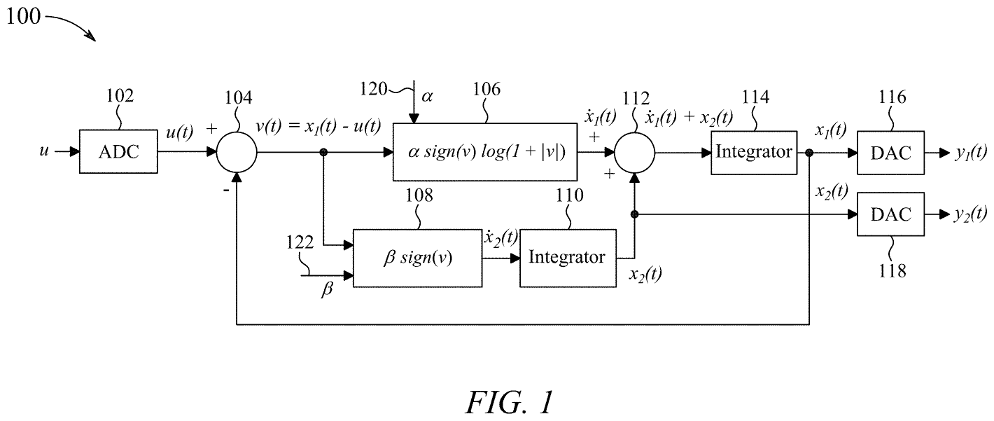

FIG. 1 illustrates an architecture of the log-sign nonlinear differentiator 100. The log-sign nonlinear differentiator 100 includes an analog-to-digital converter 102, a first adder 104, a first log-sign differentiator 106, a second log-sign differentiator 108, a first integrator 110, a second adder 112, a second integrator 114, a first digital to analog converter 116, and a second digital to analog converter 118.

The analog-to-digital converter 102 may be a circuit configured to receive an analog input signal and convert the analog signal to a digital signal u(t). The digital signal u(t) is to be tracked by the log-sign nonlinear differentiator 100. The digital signal u(t) is defined by taking u=u(t)∈C¹( [symbol] )to be a continuously measured signal such that ∥ü∥_{∞}≤c where c is a positive real number. The digital signal u(t) is provided as an input to the first adder 104 through a signal interface. The first adder 104 is a signal adder configured to receive a filtered first state signal x₁(t), subtract the filtered first state signal, x₁(t), from the digital signal, u(t), and generate an error signal, v(t). In an example, the filtered first state signal, x₁(t) of the input signal u(t) may be estimated and/or provided as feedback. The error signal v(t) is provided as an input to the first log-sign differentiator 106 and the second log-sign differentiator 108. The first log-sign differentiator 106 is configured to receive the error signal v(t). The first log-sign differentiator 106 includes a first input 120 to receive a first parameter α. The first parameter, α, is configured to cause the filtered first state signal, x₁(t), to converge asymptotically to the input signal, u(t). The first log-sign differentiator 106 estimates a first derivative, \dot{x}₁(t), of the filtered first state signal x₁(t). The first derivative, \dot{x}₁(t) is given by: \dot{x}₁(t)=x₂(t)−α ln(1+|x₁(t)−u(t)|) sign(x₁(t)−u(t)).

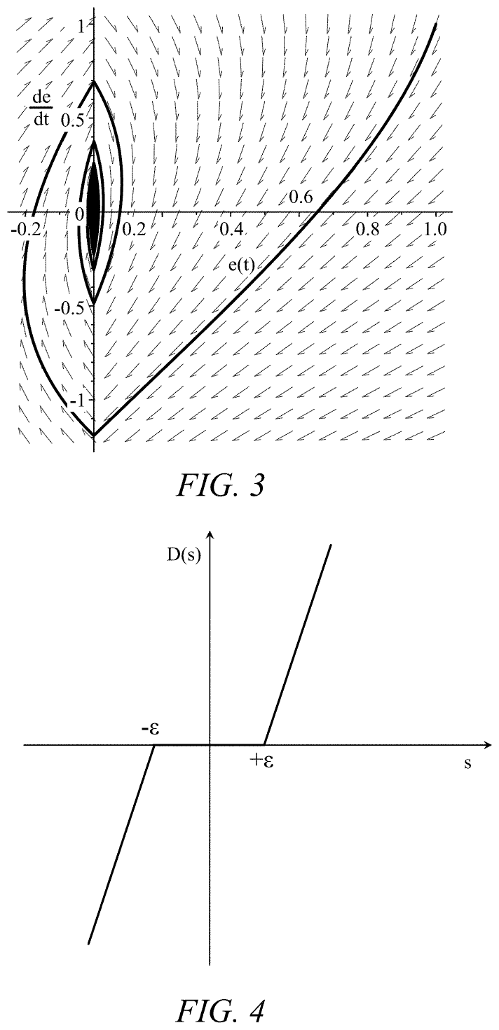

The second log-sign differentiator 108 includes a second input 122 configured to receive a second parameter, β. In some examples, the first parameter α is selected to be equal to one half of the second parameter to provide an acceptable transient behavior in the time domain. An example phase map is illustrated in FIG. 3 with α=2 and β=2.1. The second log-sign differentiator 108 is configured to receive the error signal v(t) and generate an estimate of a second derivative, \dot{x}₂(t), of the input signal, u(t). The second parameter, β, is configured to cause a second state signal, x₂(t), to converge asymptotically to the first derivative \dot{u}(t) of the input signal, u(t). In an example, the second state signal x₂(t) of the input signal may be estimated. In some examples, the log-sign nonlinear differentiator 100 calculates the first derivative, \dot{u}(t), of the input signal, u(t). The estimate of the second derivative \dot{x}₂(t) is provided as an input to the first integrator 110 that is connected in series with the second log-sign differentiator 108. The first integrator 110 integrates the estimate of the second derivative, \dot{x}₂(t) and generates the second state signal, x₂(t). The second state signal x₂(t) represents an estimate of a first derivative, \dot{u}(t), of the input signal, u(t). The first derivative \dot{x}₁(t) and the second state signal x₂(t) are provided as an input to the second adder 112. The second adder 112 is configured to add the first derivative, \dot{x}₁(t), of the filtered first state signal, x₁(t), to the second state signal, x₂(t), generating a summed signal, \dot{x}₁(t)+x₂(t). The second integrator 114 connected to the second adder 112 is configured to receive and integrate the summed signal and generate the filtered first state signal x₁(t). The first digital to analog converter 116 receives the filtered first state signal x₁(t) and converts the filtered first state signal x₁(t) to an estimate of the input signal u(t), that is y₁(t). The second digital to analog converter 118 is configured to receive the second state signal x₂(t) and convert the second state signal x₂(t) to an estimate of the first derivative \dot{u}(t) of the input signal, u(t), that is y₂(t), such that a first tracked output, y₁(t), of the log-sign nonlinear differentiator 100, is an estimate of the input signal, u(t), tracked by the log-sign nonlinear differentiator 100, and a second output, y₂(t) equals the first derivative, \dot{u}(t) of the input signal, u(t), indicating a tracked direction of the input signal, u(t).

The log-sign nonlinear differentiator 100 (also referred to as (α−β) log-sign nonlinear differentiator), determines the first derivative of u(t) with respect to time, that is provided an output of a following nonlinear system:

$${\dot{x}}_{1} ( t ) = {x}_{2} ( t ) - α ln ( 1 + \vert {x}_{1} ( t ) - u ( t ) \vert ) sign ( {x}_{1} ( t ) - u ( t ) ) , {\dot{x}}_{2} ( t ) = - β sign ( {x}_{1} ( t ) - u ( t ) ) , {y}_{2} ( t ) = {x}_{2} ( t ) , \qquad ( 1 )$$

where x₁(t) and x₂(t) are the state variables, u(t) ∈ [symbol] is the system input, and y₂(t) ∈ [symbol] is a system output. The first parameters α and the second parameter β are positive parameters that regulate a rate of convergence of the log-sign nonlinear differentiator 100. The absolute value of the second derivative, \dot{x}₂(t), of the input signal u(t) is constrained to be less than or equal to c, where c is a positive real number, and c is greater than the second parameter, β.

The log-sign nonlinear differentiator 100 determines an error e, generated by a noise component by calculating the absolute value of the difference between the estimation of the filtered first state, x₁(t) and the input signal, u(t), that is |x₁(t)−u(t)|. The log-sign nonlinear differentiator 100 determines a first derivative, ė, of the error, e, by calculating:

ė=x₂(t)−α ln(1+|x₁(t)−u(t)|) sign(x₁(t)−u(t))−\dot{u}(t);

=x₂(t)−α ln(1+|e|) sign(e)−\dot{u}(t). (2)

For e≠0, a second derivative, ë, of the error, e, is calculated by:

$$\ddot{e} = - β sign ( e ) - α \frac{\dot{e}}{1 + \vert e \vert} - \ddot{u} ( t ) . \qquad ( 3 )$$

where ü(t) represents \dot{x}₂(t). As ∥ü∥_{∞}≤c, the second derivative, ë, of the error, e, is determined by calculating:

$$\ddot{e} ∈ \{ - ( β \pm c ) sign ( e ) - α \frac{\dot{e}}{1 + \vert e \vert} \} . \qquad ( 4 )$$

To ensure the convergence of the error signal to zero, the coefficient β is selected to be greater than c.

In an embodiment, the log-sign differentiator is used to track each of a series of input signals, u(t), to provide an estimate of each signal, x₁(t), and by estimating the direction of each signal, x₂(t), where x₂(t) represents the first derivative of u(t).

### Adaptive Gain Log-Sign Differentiator

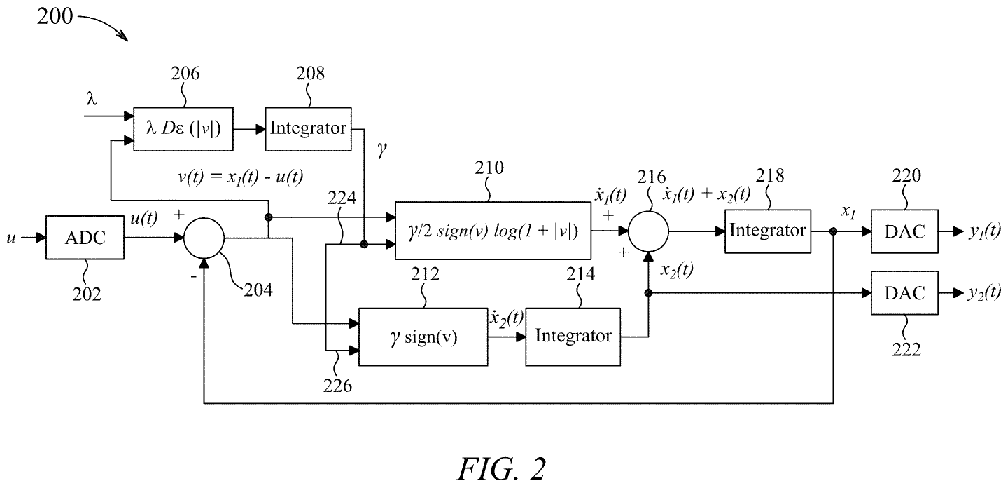

FIG. 2 illustrates an architecture of an adaptive gain log-sign nonlinear differentiator 200. The adaptive log-sign nonlinear differentiator 200 includes an analog-to-digital converter 202, a first adder 204, a deadzone function calculator 206, a first integrator 208, a first log-sign differentiator 210, a second log-sign differentiator 212, a second integrator 214, a second adder 216, a third integrator 218, a first digital to analog converter 220, and a second digital to analog converter 222.

The analog-to-digital converter 202 is configured to receive an analog input signal, u, and convert the analog signal to a digital signal, u(t). The digital signal u(t) is to be tracked by the adaptive gain log-sign nonlinear differentiator 200. The digital signal u(t) is defined by taking u=u(t)∈C¹( [symbol] )to be a continuously measured signal such that ∥ü∥_{∞}≤c where c is a positive real number. The adaptive gain log-sign nonlinear differentiator 200 samples via the signal interface, the input signal, u(t), over a plurality of sampling time periods, τ. The digital signal u(t) is provided to the first adder 204. The first adder 204 is configured to receive a filtered first state signal, x₁(t), subtract the filtered first state signal, x₁(t), from the digital signal, u(t), and generate an error signal, v(t). The adaptive gain log-sign nonlinear differentiator 200 calculates an absolute value of a difference, v(t), between the filtered first state, x₁(t) and the input signal, u(t), for each sampling time period, τ. The adaptive gain log-sign nonlinear differentiator 200 identifies a maximum of the absolute value of the difference, v(t) and defines a maximum error, ε, as the maximum of the absolute value of the difference, v(t). The adaptive gain log-sign nonlinear differentiator 200 performs a Laplace transform, [symbol] (u(s)), on the input signal, u(t), where s is a complex frequency of the input signal. The adaptive gain log-sign nonlinear differentiator 200 identifies a noise component of the input signal and calculates a deadzone function, D_{ε}(s) through the deadzone function calculator 206. The deadzone function, D_{ε}(s), is given by:

$${D}_{ε} ( s ) = \{ \begin{matrix}s - ε , & if ; s \geq ε \\ s + ε , & if ; s \leq ε \\ 0 , & if ; \vert s \vert < ε\end{matrix} . \qquad ( 5 )$$

The value of ε may be set a priori by the user with knowledge of a noise level incorporated in the measurement. However, the knowledge of upper bound of the measurement error may not be always known. Therefore, the maximum error that results from the difference |x₁(t)−u(t)| may be used to set the value of ε. An example deadzone function parametrized by the parameter ε is illustrated in FIG. 4.

The deadzone function calculator 206 is configured to receive the error signal, v(t) and a first gain parameter, λ, of a set of parameters, where λ>0, and multiply a deadzone function, D_{ε}(|u(t)−x₁(t)|), by the first gain parameter, λ, to generate a weighted deadzone function. The weighted deadzone function is provided to the first integrator 208. The first integrator 208 is configured to integrate the weighted deadzone function and generate a gain value, γ(t), of the deadzone function with respect to the complex frequency, s, for all s, to determine a gain value, γ(t), of the deadzone function, where γ(0)>0, and γ(t) is an increasing positive function of time, t. The adaptive gain log-sign nonlinear differentiator 200 sets a positive limit of the deadzone function, D_{ε}(s), to equal the maximum error, ε, and a negative limit, of the deadzone function, D_{ε}(s), to equal a negative of the maximum error, ε, of the noise component.

The error signal, v(t) is also provided to the first log-sign differentiator 210. The first log-sign differentiator 210 is configured to receive the error signal, v(t), and the gain value, γ(t), and estimate a first derivative, \dot{x}₁(t), of the filtered first state signal, x₁(t). The first log-sign differentiator 210 includes a first input 224 configured to receive the gain value, γ(t).

The second log-sign differentiator 212 is configured to receive the error signal, v(t), and the gain value, γ(t), and generate an estimate of a second derivative, \dot{x}₂(t), of the input signal, u(t). The second log-sign differentiator 212 includes a second input 226 configured to receive the gain value, γ(t). The second integrator 214, connected in series with the second log-sign differentiator 212, is configured to integrate the estimate of the second derivative, \dot{x}₂(t), and generate a second state signal, x₂(t). The second state signal, x₂(t), represents an estimate of a first derivative, \dot{u}(t), of the input signal, u(t). The second adder 216 is configured to add the first derivative, \dot{x}₁(t), of the filtered first state signal, x₁(t), to the second state signal, x₂(t), thus generating a summed signal \dot{x}₁(t)+x₂(t). The third integrator 218 is configured to integrate the summed signal and generate the filtered first state signal, x₁(t). The first digital to analog converter 220 is configured to convert the filtered first state signal, x₁(t), to an estimate of the input signal, u(t), that is y₁(t). The second digital to analog converter 222 configured to convert the second state signal to an estimate of the first derivative, \dot{u}(t) of the input signal, u(t) that is y₂(t), such that a first tracked output, y₁(t), of the adaptive gain log-sign differentiator 200, is an estimate of the input signal, u(t), and a second tracked output, y₂(t), of the adaptive gain log-sign differentiator 200, equals the first derivative, \dot{u}(t) of the input signal, u(t), indicating a tracked direction of the input signal, u(t).

The adaptive gain log-sign nonlinear differentiator 200 determines the first derivative, \dot{x}₁(t), of the filtered first state, x₁(t), by calculating:

$${\dot{x}}_{1} ( t ) = {x}_{2} ( t ) - \frac{γ}{2} ln ( 1 + \vert {x}_{1} ( t ) - u ( t ) \vert ) sign ( {x}_{1} ( t ) - u ( t ) ) . \qquad ( 6 )$$

The adaptive gain log-sign nonlinear differentiator 200 determines the first derivative, \dot{x}₂(t), of the second state signal, x₂(t), by calculating:

\dot{x}₂(t)=−γ sign (x₁(t)−u(t)). (7)

The adaptive gain log-sign nonlinear differentiator 200 determines the first derivative, \dot{γ}(t), of the gain value, γ, by calculating:

\dot{γ}=λD_{ε}(|x₁(t)−u(t)|). (8)

In some instances, when an upper bound of the second derivative of u(t) is not a priori known, differentiator parameters may be set as time-varying variables. In such situations, a structure of the adaptive gain log-sign nonlinear differentiator 200 is modified according to state-space model provided in equations (6), (7) and (8).

The adaptive gain log-sign nonlinear differentiator 200 is configured to calculate an estimate of the second derivative, \dot{x}₂(t), of the input signal, u(t). The adaptive gain log-sign nonlinear differentiator 200 may determine an error, e(t), generated by the noise component by calculating the absolute value of the difference between the estimation of the filtered first state, x₁(t) and the input signal, u(t), that is, |x₁(t)−u(t)|. For |x₁(t)−u(t)|≤ε, the adaptive gain log-sign nonlinear differentiator 200 responds in a manner similar to the log-sign nonlinear differentiator 100 (also referred to as (α−β)-log-sign differentiator) described above. When |x₁(t)−u(t)|>ε, dynamics of the error |x₁(t) −u(t) | is given by determining a second derivative, ë(t) of the error, e(t), by calculating:

$$\ddot{e} = - γ sign ( e ) - \frac{λ {D}_{ε} ( \vert e \vert )}{2} ln ( 1 + \vert e \vert ) sign ( e ) - \frac{γ}{2} \frac{\dot{e}}{1 + \vert e \vert} - \ddot{u} ( t ) , \qquad ( 9 )$$

where ü(t) represents \dot{x}₂(t), and γ here is an increasing positive function of time.

For all bounded input u(t) ∈ [symbol] such that ∥ü_{∥}<c, the trajectories of e are given by the differential inclusion:

$$\ddot{e} ∈ \{ - ( γ \pm c + \frac{λ {D}_{ε} ( \vert e \vert )}{2} ln ( 1 + \vert e \vert ) ) sign ( e ) - \frac{γ}{2} \frac{\dot{e}}{1 + \vert e \vert} \} . \qquad ( 10 )$$

Dynamics given by differential inclusion provided in equation (10) is bounded for all time. There exists a finite time T,

$$where - ( γ \pm c + \frac{λ {D}_{ε} ( \vert e \vert )}{2} ln ( 1 + \vert e \vert ) )$$

is negative and as a result, the trajectory of the error e decreases gradually until the trajectory enters a domain characterized by |e|=ε. For all time t>T; the error e(t) does not leave the boundary layer |e|≤ε.

In instances of noisy measurements, the adaptive gain nonlinear differentiator 200 has the flexibility to reliably filter the noisy input and its first derivative by selecting the appropriate dead-zone width. For inputs with large noise amplitudes, the adaptive gain nonlinear differentiator 200 selects the dead-zone large enough to stop the adaptation of the differentiator when the error signal enters the dead-zone boundary layer.

In an embodiment, the adaptive log-sign differentiator is used to track each of a series of input signals, u(t), to provide an estimate of each signal, x₁(t), and by estimating the direction of each signal, x₂(t), where x₂(t) represents the first derivative of u(t). A deadzone circuit path compensates noise components of the input signal.

### Simulation Results

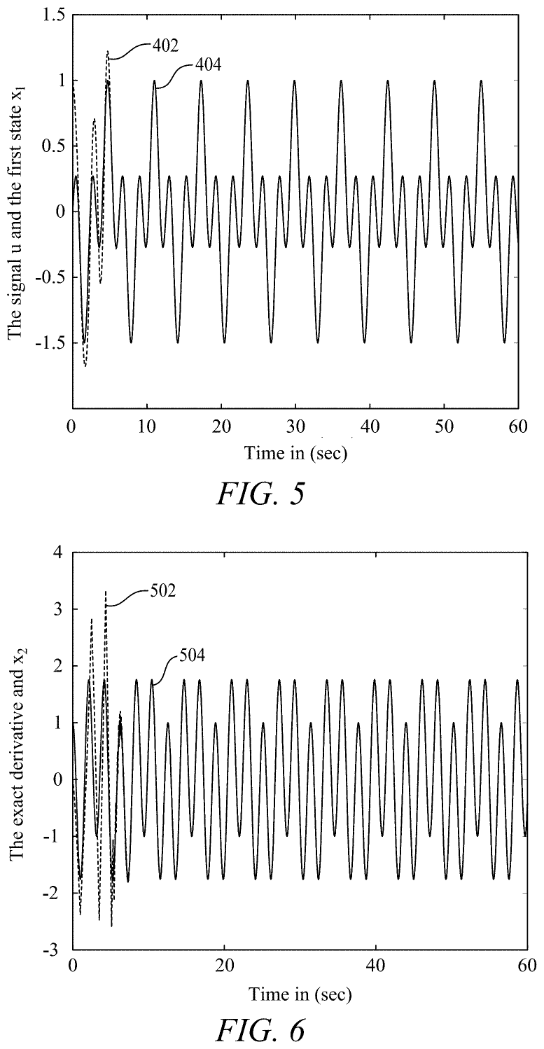

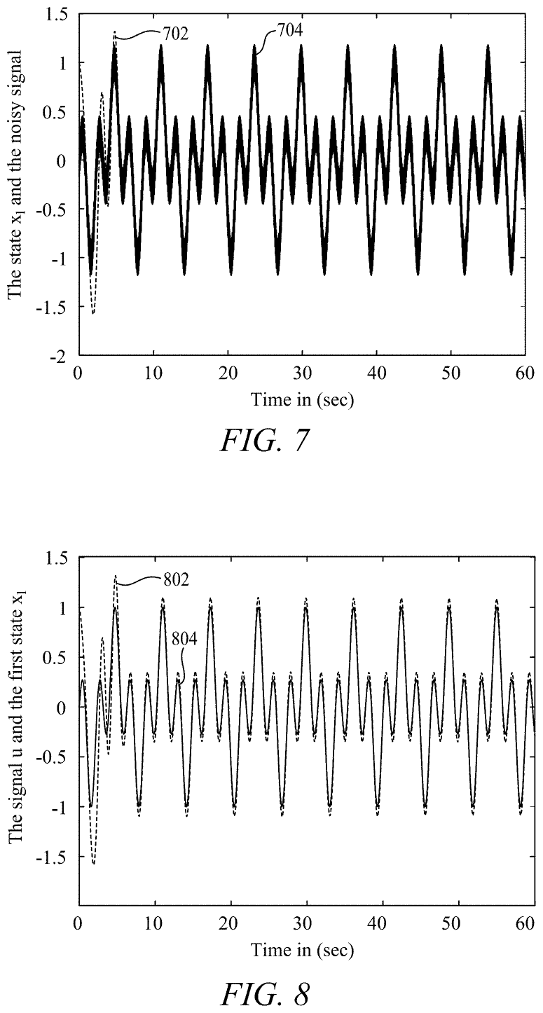

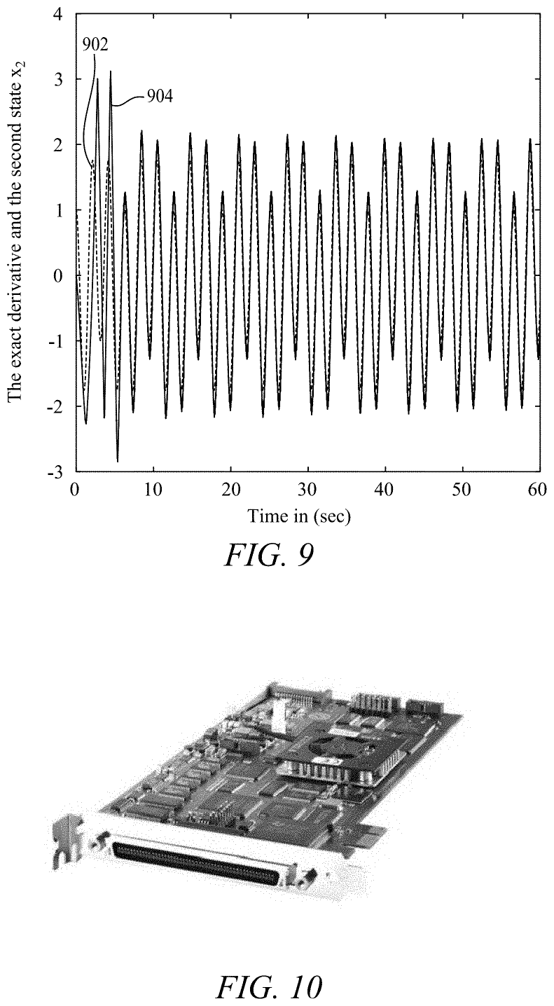

Simulation of the differentiators is described with reference to figures. In a first simulation, a signal is assumed to be free from any uncertainty; therefore, ε is set to 2·10⁻⁴. FIG. 5 illustrates a convergence of a first state x₁(t) 502 to the exact input signal u(t) 504 (that is u(t)=sin(t) cos(2t)) when time elapses. An estimate of the first derivative of u(t) (that is \dot{u}(t)) 604 is shown in FIG. 6 along with a time-derivative of the signal u(t) 602. In the simulation as shown in FIG. 6, the parameter λ is kept at 5. To test the robustness of the differentiator against additive noise, the input signal u(t) is assumed to be corrupted by a high frequency noise n(t)=0.2 sin(200t) cos(300t). The adaptive gain log-sign differentiator 200 input is composed by a low frequency signal sin(t) cos(2t) and a high frequency n(t) such that the overall signal is seen as a superposition of two signals, i.e., u(t)=sin(t) cos(2t)+0.2 sin(200t) cos(300t). The value of ε is set such that a maximum amplitude can reach the noise n(t), that is about 0.2. In FIG. 7, the signal u(t) 702 along with the first state x₁(t) 704 are depicted. FIG. 8 illustrates that the x₁(t) 802 is filtered through the adaptive gain log-sign differentiator 100 providing a good estimate of the noise-free signal along with u(t) 804. The derivative of the low-frequency signal 904 and its estimate 902 are shown in FIG. 9. After a short transient, it is noticed that the output of the adaptive gain log-sign differentiator 200 is converging to the true derivative with a bounded error.

The real-time experiments using the log-sign nonlinear differentiator 100 were implemented in a stand-alone controller board named DS1104 R&D controller board (manufactured by dSPACE, Inc, Wixom, Mich., USA 48393-2020), as shown in FIG. 10. The controller board is a cost-effective entry-level system with I/O interfaces and a real-time processor (DSP) on a single board that can be plugged directly into a Personal Computer (PC). The controller board is utilized for rapid prototyping of dynamical systems of arbitrary forms. The DS1104 controller board works with an extra Simulink package called the Real-Time Interface (RTI). The package provides Simulink coder™ blocks for graphical I/O configuration (also provided by dSPACE, Inc, Wixom, Mich., USA 48393-2020). The Real-Time Interface (RTI) offers the possibility of running models on the DS1104 controller board, configure all I/O graphically, and generate the C code via the Simulink coder™. A ControlDesk is a modular experiment and instrumentation software for electronic control unit (ECU) development (also provided by dSPACE, Inc, Wixom, Mich., USA 48393-2020). The software is utilized for rapid control prototyping (RCP; fullpass, bypass), managing the Hardware-in-the-loop simulation (HIL), recording measurements, calibration, and diagnostics. It has extra additional features that are used herein.

The log-sign nonlinear differentiator 100 was implemented in the DS1104 controller with an integration step of 10⁻⁴ (sec) with α=4.3 and β=6 and zero initial conditions. The Runge-Kutta method was used to integrate the system of equations in real-time. The Runge-Kutta method is a well known iterative method, used to approximate solutions of ordinary differential equations, in which discretization is used to calculate the solutions in small steps. The approximation of the next step is calculated from the previous one, by adding “s” terms.

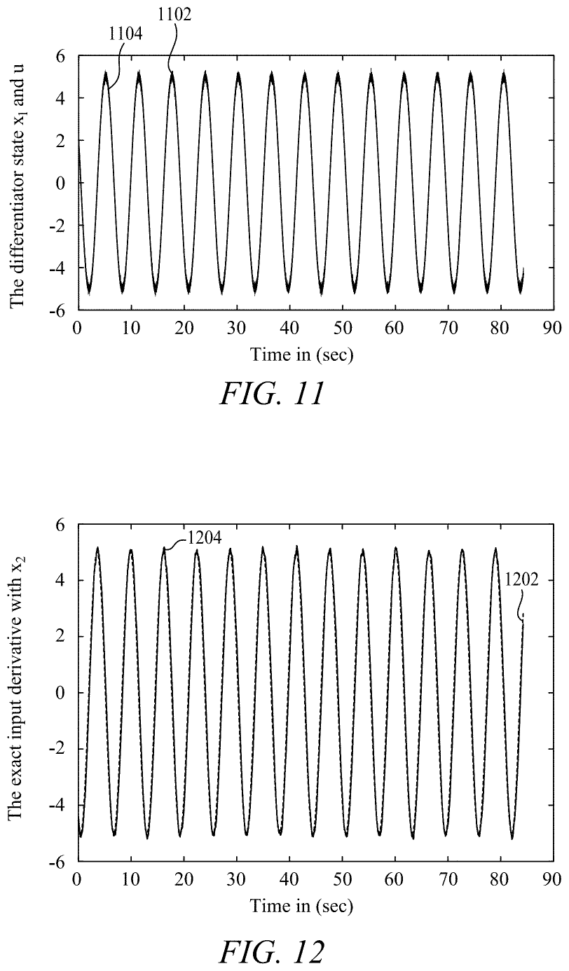

The input signal u(t) was set as 5 sin(t)+d(t) where d(t) is a band-limited white noise. The results of simulations are shown in FIG. 11 and FIG. 12. FIG. 11 illustrates the input signal u(t) 1104 corrupted by noise and the differentiator state x₁(t) 1102. FIG. 12 illustrates a noise-free signal \dot{u}(t) 1202 and the real-time differentiator state x₂(t) 1204. The results shown in FIG. 11 and FIG. 12 affirm that the log-sign nonlinear differentiator state x₂(t) converges to the exact derivative after a short period of time. FIG. 11 and FIG. 12 illustrate that the log-sign nonlinear differentiator 100 has a filtering property in the sense that the state x₂(t) is not considerably amplifying the noise attached to the input signal u(t).

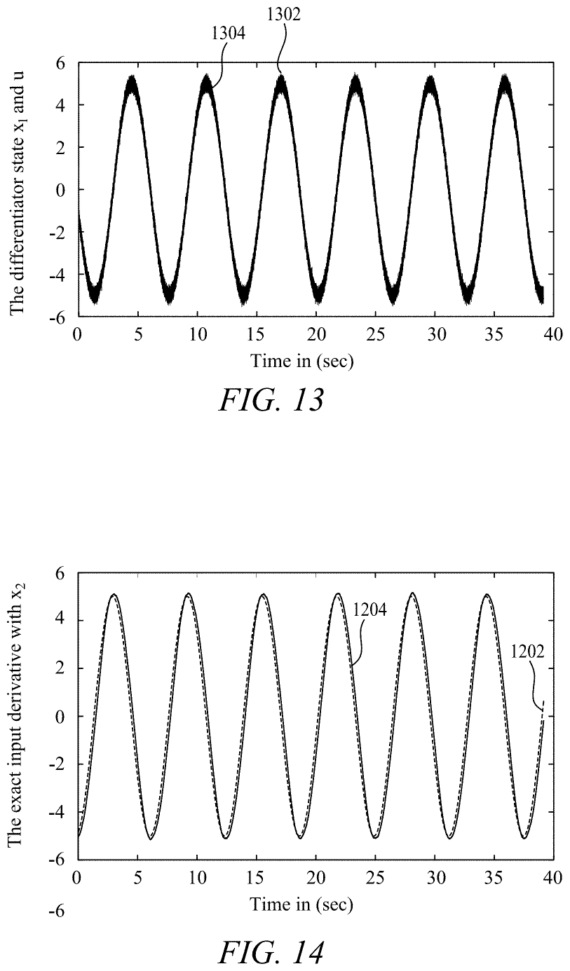

After augmenting the power of noise, the real-time data of the differentiator states x₁(t) and x₂(t) are represented in FIG. 13 and FIG. 14, respectively. FIG. 13 and FIG. 14 demonstrate that the log-sign nonlinear differentiator 100 has filtered out the noisy measurement and provided a clean derivative over the simulation time. FIG. 13 illustrates the input signal u(t) corrupted by noise 1302 and the differentiator state x₁(t) 1304. FIG. 14 illustrates a noise-free first derivative \dot{u}(t) 1402 and the real-time differentiator state x₂(t) 1404.

The log-sign nonlinear differentiator 100 and the adaptive gain log-sign differentiator 200 (referred to as “the nonlinear differentiators”) are described that are configured to reliably estimate the first derivative of noisy inputs. The nonlinear differentiators are successfully implemented in a dSPACE controller board and tested for different noise levels and different signals. The developed differentiators are designed to be applied in closed-loop control systems, target tracking, and signal processing applications. The practical results affirm that the nonlinear differentiators differentiate noisy data and reproduce the filtered signals and their respective derivatives with an error that does not exceed the maximum error in the noisy measurements.

The first embodiment is illustrated with respect to FIGS. 1-14. The first embodiment describes a method of using a log-sign nonlinear differentiator for signal tracking in a digital signal processor comprising a signal interface and circuitry for digital signal processing. The method includes receiving, via the signal interface, an input signal, u(t), to be tracked by the log-sign nonlinear differentiator, estimating, with the circuitry, a filtered first state, x₁(t) of the input signal, estimating, with the circuitry, a second state signal, x₂(t), wherein the second state signal, x₂(t), represents an estimate of a first derivative, \dot{u}(t), of the input signal, u(t), and receiving, via the signal interface, a set of parameters which cause the filtered first state, x₁(t), to converge asymptotically to the input signal, u(t), and the second state signal, x₂(t), to converge asymptotically to the first derivative \dot{u}(t) of the input signal, u(t), such that a first output, y₁(t), of the log-sign nonlinear differentiator, is an estimate of the input signal, u(t), tracked by the log-sign nonlinear differentiator, and a second output, y₂(t) equals the first derivative, \dot{u}(t) of the input signal, u(t) and indicates a direction of the input signal, u(t), tracked by the log-sign nonlinear differentiator.

The method includes determining, with the circuitry, a first derivative, \dot{x}₁(t), of the filtered first state, x₁(t), by calculating:

\dot{x}₁(t)=x₂(t)−α ln(1+|x₁(t)−u(t)|) sign(x₁(t)−u(t)),

where α is a first parameter of the set of parameters.

The method includes determining, with the circuitry, a first derivative, \dot{x}₂(t), of the second state signal, x₂(t), by calculating:

\dot{x}₂(t)=−β sign(x₁(t)−u(t),

where β is a second parameter of the set of parameters.

The method includes constraining, with the circuitry, the absolute value of the second derivative of the input signal to be less than or equal to c, where c is a positive real number, and c is greater than the second parameter, β.

The method includes selecting, via the signal interface, the first parameter, α to be equal to one half of the second parameter, β.

The method includes determining, with the circuitry, an error, e, generated by the noise component by calculating the absolute value of the difference between the estimation of the filtered first state, x₁(t) and the input signal, u(t), calculating, with the circuitry, a first derivative, \dot{u}(t), of the input signal, u(t), and determining, with the circuitry, a first derivative, ė, of the error, e, by calculating:

ė=x₂(t)−α ln(1+|x₁(t)−u(t)|) sign(x₁(t)−u(t))−\dot{u}(t)=x₂(t)−α ln(1+|e|) sign(e)−\dot{u}(t)

The method includes calculating, with the circuitry, an estimate of the second derivative, \dot{x}₂(t), of the input signal, u(t), where ∥ü∥₂₈ ≤c, and determining, with the circuitry, the second derivative, ë, of the error, e, by calculating:

$$\ddot{e} ∈ \{ - ( β \pm c ) sign ( e ) - α \frac{\dot{e}}{1 + \vert e \vert} \}$$

The method includes sampling, via the signal interface, the input signal, u(t), over a plurality of sampling time periods, τ, calculating, with the circuitry, an absolute value of a difference, v(t), between the filtered first state, x₁(t) and the input signal, u(t), for each sampling time period, τ, identifying, with the circuitry, a maximum of the absolute value of the difference, v(t), and defining, with the circuitry, the maximum error, ε, as the maximum of the absolute value of the difference, v(t).

The method includes performing, with the circuitry, a Laplace transform, [symbol] (u(s)), on the input signal, u(t), wherein s is a complex frequency of the input signal, identifying, with the circuitry, a noise component of the input signal, calculating, with the circuitry, a deadzone function, D_{ε}(s), setting, with the circuitry, a positive limit of the deadzone function, D_{ε}(s), to equal the maximum error, ε, and setting, with the circuitry, a negative limit, of the deadzone function, D_{ε}(s), to equal a negative of the maximum error, ε, of the noise component.

The deadzone function, D_{ε}(s), is given by:

$${D}_{ε} ( s ) = \{ \begin{matrix}s - ε , & if , s \geq ε \\ s + ε , & if , s \leq ε \\ 0 , & if , \vert s \vert < ε\end{matrix} .$$

The method includes selecting, via the signal interface, a first gain parameter, λ, of the set of parameters, multiplying, with the circuitry, the deadzone function, D_{ε}(|u(t)−x₁(t)|), by the first gain parameter, λ, to generate a weighted deadzone function, where λ>0, and integrating, with the circuitry, the weighted deadzone function with respect to the complex frequency, s, for all s, to determine a gain value, γ, of the deadzone function, where γ(0)>0 and γ is an increasing positive function of time, t.

The method includes determining, with the circuitry, a first derivative, \dot{x}₁(t), of the filtered first state, x₁(t), by calculating:

$${\dot{x}}_{1} ( t ) = {x}_{2} ( t ) - \frac{γ}{2} ln ( 1 + \vert {x}_{1} ( t ) - u ( t ) \vert ) sign ( {x}_{1} ( t ) - u ( t ) ) .$$

The method includes determining, with the circuitry, a first derivative, \dot{x}₂(t), of the second state signal, x₂(t), by calculating:

\dot{x}₂(t)=−γ sign(x₁(t)−u(t)).

The method includes determining, with the circuitry, a first derivative, \dot{γ}(t), of the gain value, γ, by calculating:

\dot{γ}(t)=λD_{ε}(|x₁(t)−u(t)|).

The method includes calculating, with the circuitry, an estimate of the second derivative, \dot{x}₂(t), of the input signal, u(t), determining, with the circuitry, an error, e(t), generated by the noise component by calculating the absolute value of the difference between the estimation of the filtered first state, x₁(t) and the input signal, u(t), and determining, with the circuitry, a second derivative, ë(t) of the error, e(t), by calculating:

$$\ddot{e} = - γ sign ( e ) - \frac{λ {D}_{ε} ( \vert e \vert )}{2} ln ( 1 + \vert e \vert ) sign ( e ) - \frac{γ}{2} \frac{\dot{e}}{1 + \vert e \vert} - \ddot{u} .$$

The second embodiment is illustrated with respect to FIGS. 1-14. The second embodiment describes the log-sign nonlinear differentiator 100 for signal tracking. The log-sign nonlinear differentiator 100 includes the analog-to-digital converter 102 configured to receive an analog input signal and convert the analog signal to a digital signal, u(t), the first adder 104 configured to receive a filtered first state signal, x₁(t), subtract a filtered first state signal, x₁(t), from the digital signal, u(t), and generate an error signal, v(t), the first log-sign differentiator 106 configured to receive the error signal, v(t), and estimate a first derivative, \dot{x}₁(t), of the filtered first state signal, x₁(t), the second log-sign differentiator 108 configured to receive the error signal, v(t), and generate an estimate of the second derivative, \dot{x}₂(t), of the input signal, u(t), the first integrator 110 connected in series with the second log-sign differentiator, wherein the first integrator 110 is configured to integrate the estimate of the second derivative, \dot{x}₂(t), and generate a second state signal, x₂(t), wherein the second state signal, x₂(t), represents an estimate of a first derivative, \dot{u}(t), of the input signal, u(t), the second adder 112 configured to add the first derivative, \dot{x}₁(t) , of the filtered first state signal, x₁(t), to the second state signal, x₂(t), thus generating a summed signal, the second integrator 114 configured to integrate the summed signal and generate the filtered first state signal, x₁(t), the first digital to analog converter 116 configured to convert the filtered first state signal, x₁(t) to an estimate of the input signal, u(t), and the second digital to analog converter 118 configured to convert the second state signal to an estimate of the first derivative, \dot{u}(t), of the input signal, u(t), such that a first tracked output, y₁(t), of the log-sign nonlinear differentiator 100, is an estimate of the input signal, u(t), tracked by the log-sign nonlinear differentiator 100, and a second output, y₂(t) equals the first derivative, \dot{u}(t) of the input signal, u(t), indicating a tracked direction of the input signal, u(t).

The log-sign nonlinear differentiator 100 includes the first input to the first log-sign differentiator, the first input configured to receive a first parameter, α, wherein the first parameter, α, is configured to cause the filtered first state signal, x₁(t), to converge asymptotically to the input signal, u(t), and the second input to the second log-sign differentiator, the second input configured to receive a second parameter, β, wherein the second parameter, β, is configured to cause the second state signal, x₂(t), to converge asymptotically to the first derivative \dot{u}(t) of the input signal, u(t).

The first derivative, \dot{x}₁(t), of the filtered first state signal, x₁(t), is given by:

\dot{x}₁(t)=₂(t)−α ln(1+|x₁(t)−u(t)|) sign(x₁(t)−u(t)), and

the first derivative, \dot{x}₂(t), of the second state signal, x₂(t), is given by:

\dot{x}₂(t)=−β sign(x₁(t)−u(t)).

The third embodiment is illustrated with respect to FIGS. 1-14. The third embodiment describes the adaptive gain log-sign differentiator 200 for signal tracking. The adaptive gain log-sign differentiator 200 includes the analog-to-digital converter 202 configured to receive an analog input signal and convert the analog signal to a digital signal, u(t), the first adder 204 configured to receive a filtered first state signal, x₁(t), subtract the filtered first state signal, x₁(t), from the digital signal, u(t), and generate an error signal, v(t), a deadzone function calculator 206 configured to receive the error signal, v(t) and a first gain parameter, λ, where λ>0, and multiply a deadzone function, Dε(|u(t)−x(t)|), by the first gain parameter, λ, to generate a weighted deadzone function, the first integrator 208 configured to integrate the weighted deadzone function and generate a gain value, γ(t), of the deadzone function, where γ(0)>0 and γ(t) is an increasing positive function of time, t, the first log-sign differentiator 210 configured to receive the error signal, v(t), and the gain value, γ(t), and estimate a first derivative, \dot{x}₁(t), of the filtered first state signal, x₁(t), the second log-sign differentiator 212 configured to receive the error signal, v(t), and the gain value, γ(t), and generate an estimate of the second derivative, \dot{x}₂(t), of the input signal, u(t), the second integrator 214 connected in series with the second log-sign differentiator, wherein the second integrator 214 is configured to integrate the estimate of the second derivative, \dot{x}₂(t), and generate a second state signal, x₂(t), wherein the second state signal, x₂(t), represents an estimate of a first derivative, \dot{u}(t), of the input signal, u(t), the second adder 216 configured to add the first derivative, \dot{x}₁(t), of the filtered first state signal, x₁(t), to the second state signal, x₂(t), thus generating a summed signal, the third integrator 218 configured to integrate the summed signal and generate the filtered first state signal, x₁(t), the first digital to analog converter 220 configured to convert the filtered first state signal, x₁(t), to an estimate of the input signal, u(t), and the second digital to analog converter 222 configured to convert the second state signal to an estimate of the first derivative, \dot{u}(t) of the input signal, u(t), such that a first tracked output, y₁(t), of the adaptive log-sign differentiator, is an estimate of the input signal, u(t), and a second tracked output, y₂(t), of the adaptive log-sign differentiator, equals the first derivative, \dot{u}(t) of the input signal, u(t), indicating a tracked direction of the input signal, u(t).

The adaptive gain log-sign differentiator 200 includes the first input 224 connected to the first log-sign differentiator 210, the first input 224 configured to receive the gain parameter, γ(t), wherein the first log-sign differentiator 210 is configured to estimate the first derivative, \dot{x}₁(t), of the filtered first state, x₁(t), by calculating:

\dot{x}₁(t)=x₂(t)−α ln(1+|x₁(t)−u(t)|) sign(x₁(t)−u(t)), and

The second input 226 connected to the second log-sign differentiator 212, the second input 226 configured to receive the gain parameter, γ(t), wherein the second log-sign differentiator 212 is configured to estimate the first derivative, \dot{x}₂(t), of the second state signal, x₂(t), by calculating:

\dot{x}₂(t)=−β sign(x₁(t)−u(t)).

Next, further details of the hardware description of the computing environment of FIG. 1 and FIG. 2 in which the nonlinear differentiators are implemented as a part of a computing device that includes a CPU 1501 which performs the processes described above/below.

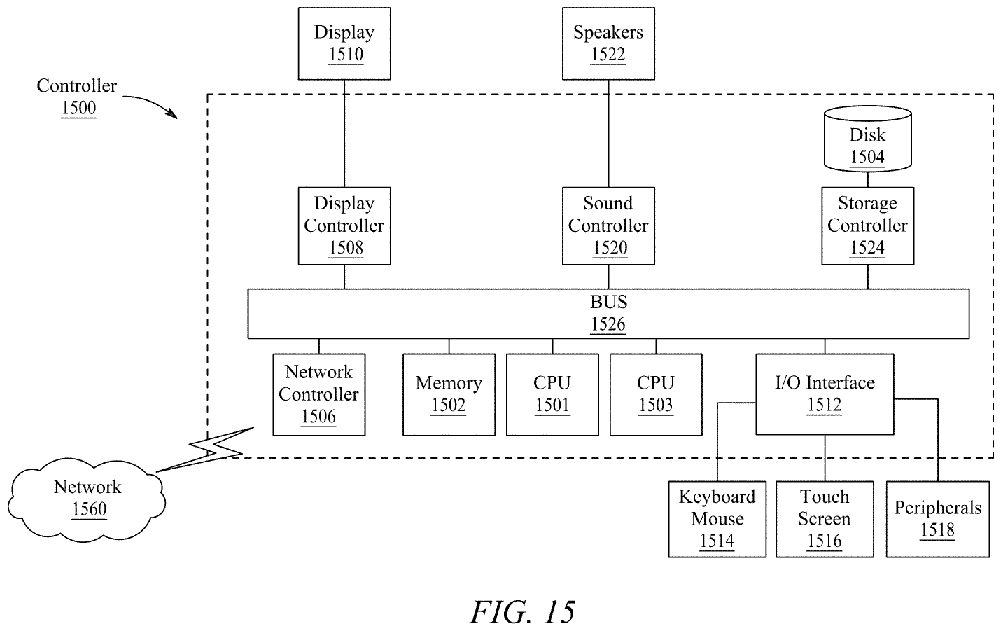

FIG. 15 is an illustration of a non-limiting example of details of computing hardware used in the computing system, according to exemplary aspects of the present disclosure. In FIG. 15, a controller 1500 is described which is a computing device (that includes, the nonlinear differentiators) and includes a CPU 1501 which performs the processes described above/below.

The process data and instructions may be stored in memory 1502. These processes and instructions may also be stored on a storage medium disk 1504 such as a hard drive (HDD) or portable storage medium or may be stored remotely.

Further, the claims are not limited by the form of the computer-readable media on which the instructions of the inventive process are stored. For example, the instructions may be stored on CDs, DVDs, in FLASH memory, RAM, ROM, PROM, EPROM, EEPROM, hard disk or any other information processing device with which the computing device communicates, such as a server or computer.

Further, the claims may be provided as a utility application, background daemon, or component of an operating system, or combination thereof, executing in conjunction with CPU 1501, 1503 and an operating system such as Microsoft Windows 7, Microsoft Windows 10, UNIX, Solaris, LINUX, Apple MAC-OS and other systems known to those skilled in the art.

The hardware elements in order to achieve the computing device may be realized by various circuitry elements, known to those skilled in the art. For example, CPU 1501 or CPU 1503 may be a Xenon or Core processor from Intel of America or an Opteron processor from AMD of America, or may be other processor types that would be recognized by one of ordinary skill in the art. Alternatively, the CPU 1501, 1503 may be implemented on an FPGA, ASIC, PLD or using discrete logic circuits, as one of ordinary skill in the art would recognize. Further, CPU 1501, 1503 may be implemented as multiple processors cooperatively working in parallel to perform the instructions of the inventive processes described above.

The computing device in FIG. 15 also includes a network controller 1506, such as an Intel Ethernet PRO network interface card from Intel Corporation of America, for interfacing with network 1560. As can be appreciated, the network 1560 can be a public network, such as the Internet, or a private network such as an LAN or WAN network, or any combination thereof and can also include PSTN or ISDN sub-networks. The network 1560 can also be wired, such as an Ethernet network, or can be wireless such as a cellular network including EDGE, 3G and 4G wireless cellular systems. The wireless network can also be WiFi, Bluetooth, or any other wireless form of communication that is known.

The computing device further includes a display controller 1508, such as a NVIDIA GeForce GTX or Quadro graphics adaptor from NVIDIA Corporation of America for interfacing with display 1510, such as a Hewlett Packard HPL2445w LCD monitor. A general purpose I/O interface 1512 interfaces with a keyboard and/or mouse 1514 as well as a touch screen panel 1516 on or separate from display 1510. General purpose I/O interface also connects to a variety of peripherals 1518 including printers and scanners, such as an OfficeJet or DeskJet from Hewlett Packard.

A sound controller 1520 is also provided in the computing device such as Sound Blaster X-Fi Titanium from Creative, to interface with speakers/microphone 1522 thereby providing sounds and/or music.

The general purpose storage controller 1524 connects the storage medium disk 1504 with communication bus 1526, which may be an ISA, EISA, VESA, PCI, or similar, for interconnecting all of the components of the computing device. A description of the general features and functionality of the display 1510, keyboard and/or mouse 1514, as well as the display controller 1508, storage controller 1524, network controller 1506, sound controller 1520, and general purpose I/O interface 1512 is omitted herein for brevity as these features are known.

The exemplary circuit elements described in the context of the present disclosure may be replaced with other elements and structured differently than the examples provided herein.

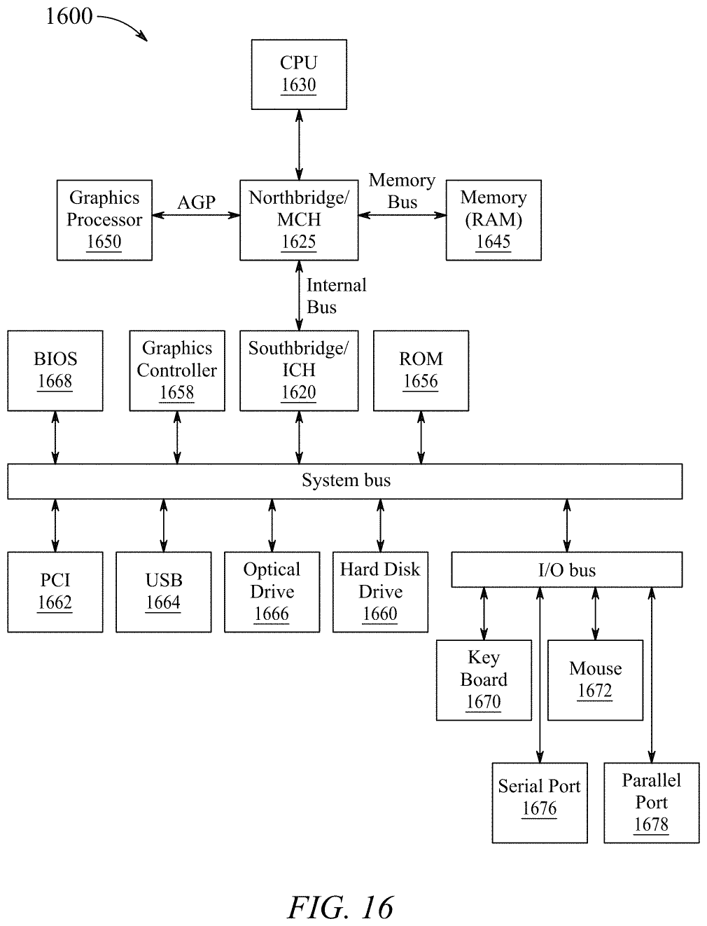

Moreover, circuitry configured to perform features described herein may be implemented in multiple circuit units (e.g., chips), or the features may be combined in circuitry on a single chipset, as shown on FIG. 16.

FIG. 16 shows a schematic diagram of a data processing system, according to certain embodiments, for performing the functions of the exemplary embodiments. The data processing system is an example of a computer in which code or instructions implementing the processes of the illustrative embodiments may be located.

In FIG. 16, data processing system 1600 employs a hub architecture including a north bridge and memory controller hub (NB/MCH) 1625 and a south bridge and input/output (I/O) controller hub (SB/ICH) 1620. The central processing unit (CPU) 1630 is connected to NB/MCH 1625. The NB/MCH 1625 also connects to the memory 1645 via a memory bus, and connects to the graphics processor 1650 via an accelerated graphics port (AGP). The NB/MCH 1625 also connects to the SB/ICH 1620 via an internal bus (e.g., a unified media interface or a direct media interface). The CPU Processing unit 1630 may contain one or more processors and even may be implemented using one or more heterogeneous processor systems.

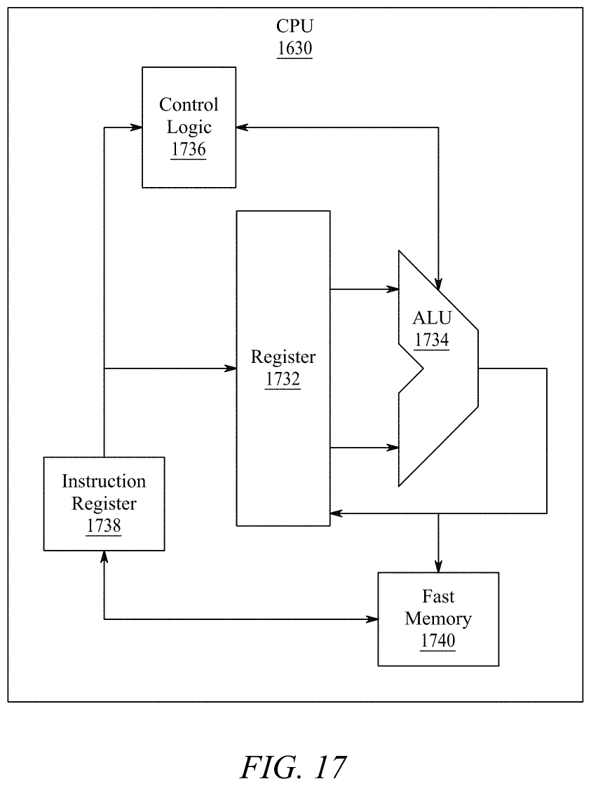

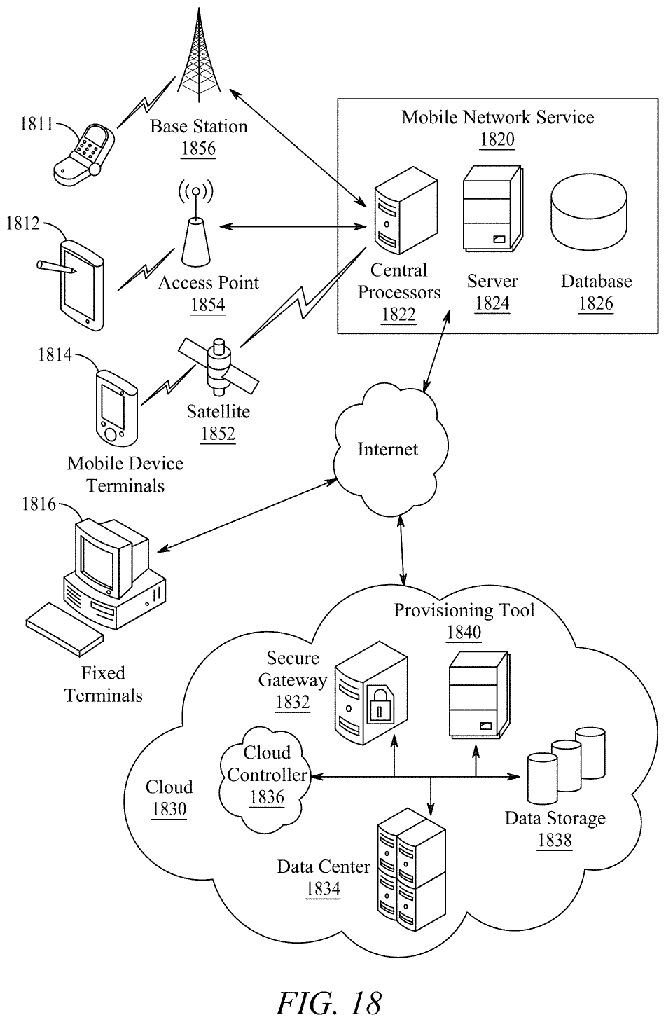

For example, FIG. 17 shows one implementation of CPU 1630. In one implementation, the instruction register 1738 retrieves instructions from the fast memory 1740. At least part of these instructions are fetched from the instruction register 1738 by the control logic 1736 and interpreted according to the instruction set architecture of the CPU 1630. Part of the instructions can also be directed to the register 1732. In one implementation the instructions are decoded according to a hardwired method, and in another implementation the instructions are decoded according to a microprogram that translates instructions into sets of CPU configuration signals that are applied sequentially over multiple clock pulses. After fetching and decoding the instructions, the instructions are executed using the arithmetic logic unit (ALU) 1734 that loads values from the register 1732 and performs logical and mathematical operations on the loaded values according to the instructions. The results from these operations can be feedback into the register and/or stored in the fast memory 1740. According to certain implementations, the instruction set architecture of the CPU 1630 can use a reduced instruction set architecture, a complex instruction set architecture, a vector processor architecture, a very large instruction word architecture. Furthermore, the CPU 1630 can be based on the Von Neuman model or the Harvard model. The CPU 1630 can be a digital signal processor, an FPGA, an ASIC, a PLA, a PLD, or a CPLD. Further, the CPU 1630 can be an x86 processor by Intel or by AMD; an ARM processor, a Power architecture processor by, e.g., IBM; a SPARC architecture processor by Sun Microsystems or by Oracle; or other known CPU architecture.

Referring again to FIG. 16, the data processing system 1600 can include that the SB/ICH 1620 is coupled through a system bus to an I/O Bus, a read only memory (ROM) 1656, universal serial bus (USB) port 1664, a flash binary input/output system (BIOS) 1668, and a graphics controller 1658. PCI/PCIe devices can also be coupled to SB/ICH 1688 through a PCI bus 1662.

The PCI devices may include, for example, Ethernet adapters, add-in cards, and PC cards for notebook computers. The Hard disk drive 1660 and CD-ROM 1666 can use, for example, an integrated drive electronics (IDE) or serial advanced technology attachment (SATA) interface. In one implementation the I/O bus can include a super I/O (SIO) device.

Further, the hard disk drive (HDD) 1660 and optical drive 1666 can also be coupled to the SB/ICH 1620 through a system bus. In one implementation, a keyboard 1670, a mouse 1672, a parallel port 1678, and a serial port 1676 can be connected to the system bus through the I/O bus. Other peripherals and devices that can be connected to the SB/ICH 1620 using a mass storage controller such as SATA or PATA , an Ethernet port, an ISA bus, a LPC bridge, SMBus, a DMA controller, and an Audio Codec.

Moreover, the present disclosure is not limited to the specific circuit elements described herein, nor is the present disclosure limited to the specific sizing and classification of these elements. For example, the skilled artisan will appreciate that the circuitry described herein may be adapted based on changes on battery sizing and chemistry, or based on the requirements of the intended back-up load to be powered.

The functions and features described herein may also be executed by various distributed components of a system. For example, one or more processors may execute these system functions, wherein the processors are distributed across multiple components communicating in a network. The distributed components may include one or more client and server machines, which may share processing, as shown by FIG. 10, in addition to various human interface and communication devices (e.g., display monitors, smart phones, tablets, personal digital assistants (PDAs)). The network may be a private network, such as a LAN or WAN, or may be a public network, such as the Internet. Input to the system may be received via direct user input and received remotely either in real-time or as a batch process. Additionally, some implementations may be performed on modules or hardware not identical to those described. Accordingly, other implementations are within the scope that may be claimed.

The above-described hardware description is a non-limiting example of corresponding structure for performing the functionality described herein.

Obviously, numerous modifications and variations of the present disclosure are possible in light of the above teachings. It is therefore to be understood that within the scope of the appended claims, the invention may be practiced otherwise than as specifically described herein.

1. A method of using a log-sign nonlinear differentiator for signal tracking in a digital signal processor comprising a signal interface and a circuitry for digital signal processing, comprising:
receiving, via the signal interface, an input signal, u(t), to be tracked by the log-sign nonlinear differentiator;
estimating, with the circuitry, a filtered first state, x₁(t) of the input signal;
estimating, with the circuitry, a second state signal, x₂(t), wherein the second state signal, x₂(t), represents an estimate of a first derivative, \dot{u}(t), of the input signal, u(t); and
receiving, via the signal interface, a set of parameters which cause the filtered first state, x₁(t), to converge asymptotically to the input signal, u(t), and the second state signal, x₂(t), to converge asymptotically to the first derivative \dot{u}(t) of the input signal, u(t), such that a first output, y₁(t), of the log-sign nonlinear differentiator, is an estimate of the input signal, u(t), tracked by the log-sign nonlinear differentiator, and a second output, y₂(t) equals the first derivative, \dot{u}(t) of the input signal, u(t) and indicates a direction of the input signal, u(t), tracked by the log-sign nonlinear differentiator.

2. The method of claim 1, further comprising;
determining, with the circuitry, a first derivative, \dot{x}₁(t) of the filtered first state, x₁(t), by calculating:
\dot{x}₁(t)=x₂(t)−α ln(1+|x₁(t)−u(t)|) sign(x₁(t)−u(t)),
where α is a first parameter of the set of parameters.

3. The method of claim 2, further comprising;
determining, with the circuitry, a first derivative, \dot{x}₂(t), of the second state signal, x₂(t), by calculating:
\dot{x}₂(t)=−β sign(x₁(t)−u(t)),
where β is a second parameter of the set of parameters.

4. The method of claim 3, further comprising:
constraining, with the circuitry, the absolute value of a second derivative of the input signal to be less than or equal to c, where c is a positive real number, and c is greater than the second parameter, β.

5. The method of claim 4, further comprising:
selecting, via the signal interface, the first parameter, α to be equal to one half of the second parameter, β.

6. The method of claim 5, further comprising:
determining, with the circuitry, an error, e, generated by the noise component by calculating the absolute value of the difference between the estimation of the filtered first state, x₁(t) and the input signal, u(t);
calculating, with the circuitry, a first derivative, \dot{u}(t), of the input signal, u(t); and
determining, with the circuitry, a first derivative, ė, of the error, e, by calculating:
ė=x₂(t)−60 ln(1+|x₁(t)−u(t)|) sign(x₁(t)−u(t))−\dot{u}(t)=x₂(t)−α ln(1+|e|) sign (e)−\dot{u}(t).

7. The method of claim 6, further comprising:
calculating, with the circuitry, an estimate of a second derivative, \dot{x}₂(t), of the input signal, u(t), where:
∥ü∥_{∞}≤c; and
determining, with the circuitry, a second derivative, ë, of the error, e, by calculating:
$$\ddot{e} ∈ \{ - ( β \pm c ) sign ( e ) - α \frac{\dot{e}}{1 + \vert e \vert} \}$$

8. The method of claim 1, further comprising:
sampling, via the signal interface, the input signal, u(t), over a plurality of sampling time periods, τ;
calculating, with the circuitry, an absolute value of a difference, v(t), between the filtered first state, x₁(t) and the input signal, u(t), for each sampling time period, τ;
identifying, with the circuitry, a maximum of the absolute value of the difference, v(t); and
defining, with the circuitry, a maximum error, ε, as the maximum of the absolute value of the difference, v(t).

9. The method of claim 8, further comprising:
performing, with the circuitry, a Laplace transform, [symbol] (u(s)), on the input signal, u(t), wherein s is a complex frequency of the input signal;
identifying, with the circuitry, a noise component of the input signal;
calculating, with the circuitry, a deadzone function, D_{ε}(s);
setting, with the circuitry, a positive limit of the deadzone function, D_{ε}(s), to equal the maximum error, ε; and
setting, with the circuitry, a negative limit, of the deadzone function, D_{ε}(s), to equal a negative of the maximum error, ε, of the noise component.

10. The method of claim 9, wherein the deadzone function, D_{ε}(s), is given by:
$${D}_{ε} ( s ) = \{ \begin{matrix}s - ε , & if ; s \geq ε \\ s + ε , & if ; s \leq ε \\ 0 , & if ; \vert s \vert < ε\end{matrix} .$$

11. The method of claim 10, further comprising:
selecting, via the signal interface, a first gain parameter, λ, of the set of parameters;
multiplying, with the circuitry, the deadzone function, D_{ε}(|u(t)−x1(t)|), by the first gain parameter, λ, to generate a weighted deadzone function, where λ>0; and
integrating, with the circuitry, the weighted deadzone function with respect to the complex frequency, s, for all s, to determine a gain value, γ(t), of the deadzone function, where γ(0)>0 and γ(t) is an increasing positive function of time, t.

12. The method of claim 11, further comprising:
determining, with the circuitry, a first derivative, \dot{x}₁(t), of the filtered first state, x₁(t), by calculating:
$${\dot{x}}_{1} ( t ) = {x}_{2} ( t ) - \frac{γ}{2} ln ( 1 + \vert {x}_{1} ( t ) - u ( t ) \vert ) sign ( {x}_{1} ( t ) - u ( t ) ) .$$

13. The method of claim 12, further comprising:
determining, with the circuitry, a first derivative, \dot{x}₂(t), of the second state signal, x₂(t), by calculating:
\dot{x}₂(t)=−γ sign(x₁(t)−u(t)).

14. The method of claim 13, further comprising:
determining, with the circuitry, a first derivative, \dot{γ}(t), of the gain value, γ, by calculating:
\dot{γ}(t)=λD_{ε}(|x₁(t)−u(t)|).

15. The method of claim 14, further comprising:
calculating, with the circuitry, an estimate of a second derivative, \dot{x}₂(t), of the input signal, u(t);
determining, with the circuitry, an error, e(t), generated by the noise component by calculating the absolute value of the difference between the estimation of the filtered first state, x₁(t) and the input signal, u(t); and
determining, with the circuitry, a second derivative, ë(t) of the error, e(t), by calculating:
$$\ddot{e} = - γ sign ( e ) - \frac{λ {D}_{ε} ( \vert e \vert )}{2} ln ( 1 + \vert e \vert ) sign ( e ) - \frac{γ}{2} \frac{\dot{e}}{1 + \vert e \vert} - \ddot{u} ( t ) ,$$
where ü(t) represents \dot{x}₂(t).

16. A log-sign nonlinear differentiator for signal tracking, comprising:
an analog-to-digital converter configured to receive an analog input signal and convert the analog signal to a digital signal, u(t);
a first adder configured to receive a filtered first state signal, x₁(t), subtract a filtered first state signal, x₁(t), from the digital signal, u(t), and generate an error signal, v(t);
a first log-sign differentiator configured to receive the error signal, v(t), and estimate a first derivative, \dot{x}₁(t), of the filtered first state signal, x₁(t);
a second log-sign differentiator configured to receive the error signal, v(t), and generate an estimate of a second derivative, \dot{x}₂(t), of the input signal, u(t);
a first integrator connected in series with the second log-sign differentiator, wherein the first integrator is configured to integrate the second derivative, \dot{x}₂(t), and generate a second state signal, x₂(t), wherein the second state signal, x₂(t), represents an estimate of a first derivative, \dot{u}(t), of the input signal, u(t);
a second adder configured to add the first derivative, \dot{x}₁(t), of the filtered first state signal, x₁(t), to the second state signal, x₂(t), thus generating a summed signal;
a second integrator configured to integrate the summed signal and generate the filtered first state signal, x₁(t);
a first digital to analog converter configured to convert the filtered first state signal, x₁(t) to an estimate of the input signal, u(t); and
a second digital to analog converter configured to convert the second state signal to an estimate of the first derivative, \dot{u}(t), of the input signal, u(t), such that a first tracked output, y₁(t), of the log-sign nonlinear differentiator, is an estimate of the input signal, u(t), tracked by the log-sign nonlinear differentiator, and a second output, y₂(t) equals the first derivative, \dot{u}(t) of the input signal, u(t), indicating a tracked direction of the input signal, u(t).

17. The log-sign nonlinear differentiator of claim 16, comprising:
a first input to the first log-sign differentiator, the input configured to receive a first parameter, α, wherein the first parameter, α, is configured to cause the filtered first state signal, x₁(t), to converge asymptotically to the input signal, u(t); and
a second input to the second log-sign differentiator, the second input configured to receive a second parameter, wherein the second parameter, β, is configured to cause the second state signal, x₂(t), to converge asymptotically to the first derivative \dot{u}(t) of the input signal, u(t).

18. The log-sign nonlinear differentiator of claim 17, wherein:
the first derivative, \dot{x}₁(t), of the filtered first state signal, x₁(t), is given by:
\dot{x}₁(t)=x₂(t)−α ln(1−|x₁(t)−u(t)|) sign(x₁(t)−u(t)),
and
the first derivative, \dot{x}₂(t), of the second state signal, x₂(t), is given by:
\dot{x}₂(t)=−β sign(x₁(t)−u(t)).

19. An adaptive gain log-sign differentiator for signal tracking, comprising:
an analog-to-digital converter configured to receive an analog input signal and convert the analog signal to a digital signal, u(t);
a first adder configured to receive a filtered first state signal, x₁(t), subtract the filtered first state signal, x₁(t), from the digital signal, u(t), and generate an error signal, v(t);
a deadzone function calculator configured to receive the error signal, v(t) and a first gain parameter, λ, where λ>0, and multiply a deadzone function, D_{ε}(|u(t)−x₁(t)|)), by the first gain parameter, λ, to generate a weighted deadzone function;
a first integrator configured to integrate the weighted deadzone function and generate a gain value, γ(t), of the deadzone function, where γ(0)>0 and γ(t) is an increasing positive function of time, t;
a first log-sign differentiator configured to receive the error signal, v(t), and the gain value, γ(t), and estimate a first derivative, \dot{x}₁(t), of the filtered first state signal, x₁(t);
a second log-sign differentiator configured to receive the error signal, v(t), and the gain value, γ(t), and generate an estimate of a second derivative, \dot{x}₂(t), of the input signal, u(t);
a second integrator connected in series with the second log-sign differentiator, wherein the second integrator is configured to integrate the second derivative, \dot{x}₂(t), and generate a second state signal, x₂(t), wherein the second state signal, x₂(t), represents an estimate of a first derivative, \dot{u}(t), of the input signal, u(t);
a second adder configured to add the first derivative, \dot{x}₁(t), of the filtered first state signal, x₁(t), to the second state signal, x₂(t), thus generating a summed signal;
a third integrator configured to integrate the summed signal and generate the filtered first state signal, x₁(t);
a first digital to analog converter configured to convert the filtered first state signal, x₁(t), to an estimate of the input signal, u(t); and
a second digital to analog converter configured to convert the second state signal to an estimate of the first derivative, \dot{u}(t) of the input signal, u(t), such that a first tracked output, y₁(t), of the adaptive log-sign differentiator, is an estimate of the input signal, u(t), and a second tracked output, y₂(t), of the adaptive log-sign differentiator, equals the first derivative, \dot{u}(t) of the input signal, u(t), indicating a tracked direction of the input signal, u(t).

20. The adaptive gain log-sign differentiator, further comprising:
a first input connected to the first log-sign differentiator, the first input configured to receive the gain value, γ(t), wherein the first log-sign differentiator is configured to estimate the first derivative, \dot{x}₁(t), of the filtered first state, x₁(t), by calculating:
$${\dot{x}}_{1} ( t ) = {x}_{2} ( t ) - \frac{γ}{2} ln ( 1 + \vert {x}_{1} ( t ) - u ( t ) \vert ) sign ( {x}_{1} ( t ) - u ( t ) ) ,$$
and
a second input connected to the second log-sign differentiator, the second input configured to receive the gain value, γ(t), wherein the second log-sign differentiator is configured to estimate the first derivative, \dot{x}₂(t), of the second state, x₂(t), by calculating:
\dot{x}₂(t)=−γ sign(x₁(t)−u(t)).
